(19) United States
(12) Patent Application Publication
(10) Pub. No.: US 2026/0032855 A1
(43) Pub. Date: Jan. 29, 2026

(54) Cooling Apparatus for Power Module

(71) Applicants: HYUNDAI MOTOR COMPANY, Seoul (KR); KIA CORPORATION, Seoul (KR)

(72) Inventors: Se Heun Kwon, Hwaseong-si (KR); Hyong Joon Park, Hwaseong-si (KR); Sang Hun Lee, Hwaseong-si (KR)

(73) Assignees: HYUNDAI MOTOR COMPANY, Seoul (KR); KIA CORPORATION, Seoul (KR)

(21) Appl. No.: 18/967,610

(22) Filed: Dec. 3, 2024

(30) Foreign Application Priority Data
Jul. 29, 2024 (KR) 10-2024-0100348

(51) Int. Cl. H05K 7/20

(52) U.S. Cl. CPC H05K 7/202; H05K 7/20909

(57) ABSTRACT

According to the present disclosure, a vertical turbulent flow of a cooling fluid, which is created by spraying the cooling fluid to a heat generation surface with cooling fins of a fin plate provided on a manifold cover, provides cooling efficiency, improves fluidity of the cooling fluid, and minimizes a loss of a flow rate. In addition, a cooling apparatus for a power module is introduced in which a difference in cooling performance occurs between cooling channel parts corresponding to power modules in the manifold cover, such that the power modules are cooled in a balanced manner, cooling imbalance is eliminated, the power module is stabilized, and the performance is maintained.

### CROSS-REFERENCE TO RELATED APPLICATION

The present application claims priority to Korean Patent Application No. 10-2024-0100348, filed on Jul. 29, 2024, the entire contents of which are incorporated herein by this reference.

### TECHNICAL FIELD

The present disclosure relates to a cooling apparatus for a power module that cools a power module by using a cooling fluid.

### BACKGROUND

The power module is applied to an electric vehicle or the like and controls a (e.g., high) voltage and a (e.g., large) current. Therefore, the amount of heat generation is (e.g., very) large, and an appropriate cooling process may be beneficial to maintain performance and durability. To this end, a cooling fluid is used to cool the power module, or waste heat from the power module is used to heat a mobility vehicle or the like.

In order to cool the power module, a cooling apparatus is connected to one side surface of the power module, and the cooling fluid flows in the cooling apparatus. However, because a tube or fin structure, which is simple and generally used, is applied to the cooling apparatus, cooling efficiency is low.

In particular, in a case that the power module is provided as a plurality of power modules, the efficiency in cooling the power module, which is cooled later among the plurality of power modules, deteriorates in comparison with the efficiency in cooling the power module that is cooled first. The cooling imbalance related to the power modules degrades the performance of the power modules.

As described above, the cooling efficiency of the electric vehicle or the like is closely associated with overall energy efficiency of the mobility vehicles and greatly affects the operation of maintaining durability or performance of the power module. Accordingly, improving the efficiency in cooling the power module by applying a new cooling structure may be beneficial.

The foregoing explained as the background is intended to aid in the understanding of the background of the present disclosure, and is not intended to mean that the present disclosure falls within the purview of the related art that is already known to those skilled in the art.

### SUMMARY

The present disclosure is proposed to solve these problems and aims to provide a cooling apparatus for a power module in which a vertical turbulent flow of a cooling fluid, which is created by spraying the cooling fluid to a heat generation surface with cooling fins of a fin plate provided on a manifold cover, provides cooling efficiency, improves fluidity of the cooling fluid, and minimizes a loss of a flow rate.

In order to achieve the above-mentioned object, a cooling apparatus for a power module according to the present disclosure includes a plurality of power modules disposed to be spaced apart from one another, a manifold cover in which an inlet path and an outlet path extend in a first direction so that a cooling fluid flows therethrough, the inlet path and the outlet path are disposed to be spaced apart from each other in a second direction intersecting the first direction, a plurality of cooling channel parts are disposed in parallel in the first direction between the inlet path and the outlet path and matched with the power modules, and the cooling channel parts each include a first channel configured to communicate with the inlet path, and a second channel configured to communicate with the outlet path, and a fin plate embedded in the manifold cover, configured to adjoin the power modules, and having a plurality of cooling fins extending in the first direction so that the cooling fluid introduced into the first channel flows between the cooling fins and then flows to the second channel.

The manifold cover may be formed such that a cross-sectional area of the inlet path decreases in the first direction.

The manifold cover may be formed such that an inner wall surface opposite to the cooling channel part is gradient toward the cooling channel part in the first direction.

The manifold cover may be formed such that an inner wall surface opposite to the cooling channel part is gradually stepped and protrudes toward the cooling channel part in the first direction.

A plurality of flow rate distribution portions may be formed in the inlet path of the manifold cover in the first direction and matched with the cooling channel parts, and the flow rate distribution portion may be formed such that a part of the cooling fluid flowing in the inlet path moves to each of the cooling channel parts.

The flow rate distribution portion may extend obliquely or curvedly in the first direction.

The flow rate distribution portion matched with each of the cooling channel parts may be formed such that a flow rate of the cooling fluid sequentially and gradually increases in the first direction.

The manifold cover may have an inlet portion formed at one side of the inlet path so that the cooling fluid is introduced through the inlet portion, and an outlet portion formed at the other side of the outlet path so that the cooling fluid is discharged through the outlet portion, and guide portions may be respectively formed in the inlet portion and the outlet portion and guide the flow of the cooling fluid.

The guide portion at a side of the inlet portion may extend so that the cooling fluid introduced through an inlet flows toward the inlet path, and the guide portion at a side of the outlet portion may extend so that the cooling fluid flowing in the outlet path flows toward an outlet.

The plurality of cooling channel parts may be configured such that the number of first channels or the number of second channels gradually increases in the first direction.

The fin plate may have a plurality of fluid diffusion portions formed in a part of the inlet path or the outlet path or formed around the cooling channel part.

The fluid diffusion portion may include one or more protrusions protruding from the fin plate, and the number of protrusions of the fluid diffusion portions may gradually increase in the first direction.

The plurality of protrusions of the fluid diffusion portions may be spaced apart from one another in the first direction and intersect in the second direction.

A cross-section of the fluid diffusion portion may be formed in a polygonal or circular shape.

The cooling fin may protrude from the fin plate, and a cross-sectional area of a protruding end may gradually decrease in a protruding direction.

A cross-sectional shape of an end of the cooling fin may be a triangular or curved shape.

According to the cooling apparatus for a power module having the above-mentioned structure, the vertical turbulent flow of the cooling fluid, which is created by spraying the cooling fluid to the heat generation surface with the cooling fins of the fin plate provided on the manifold cover, provides the cooling efficiency, improves the fluidity of the cooling fluid, and minimizes a loss of the flow rate.

In addition, a difference in cooling performance occurs between the cooling channel parts corresponding to the power modules in the manifold cover, such that the power modules are cooled in a balanced manner, the cooling imbalance is eliminated, the power module is stabilized, and the performance is maintained.

### BRIEF DESCRIPTION OF THE DRAWINGS

FIG. 1 is a view illustrating a cooling apparatus for a power module according to an embodiment of the present disclosure.

FIGS. 2A and 2B is a view illustrating a manifold cover and a fin plate of the cooling apparatus for a power module illustrated in FIG. 1.

FIG. 3 is a view illustrating an embodiment of a cooling channel part of the manifold cover of the present disclosure.

FIG. 4 is a view illustrating the cooling channel part and cooling fins of the present disclosure.

FIG. 5 is a view illustrating another embodiment of the cooling channel part of the manifold cover of the present disclosure.

FIG. 6 is a view illustrating still another embodiment of the cooling channel part of the manifold cover of the present disclosure.

FIG. 7 is a view illustrating yet another embodiment of the cooling channel part of the manifold cover of the present disclosure.

FIG. 8 is a view illustrating another embodiment of the cooling fin of the fin plate of the present disclosure.

FIG. 9 is a view illustrating an embodiment of the cooling fin of the fin plate of the present disclosure.

### DETAILED DESCRIPTION

Hereinafter, embodiments disclosed in the present specification will be described in detail with reference to the accompanying drawings. The same or similar constituent elements are assigned with the same reference numerals regardless of reference numerals, and the repetitive description thereof will be omitted.

The suffixes “module”, “unit”, “part”, and “portion” used to describe constituent elements in the following description are used together or interchangeably in order to facilitate the description, but the suffixes themselves do not have distinguishable meanings or functions.

In the description of the embodiments disclosed in the present specification, the specific descriptions of publicly known related technologies will be omitted when it is determined that the specific descriptions may obscure the subject matter of the embodiments disclosed in the present specification. In addition, it should be interpreted that the accompanying drawings are provided to allow those skilled in the art to easily understand the embodiments disclosed in the present specification, and the technical spirit disclosed in the present specification is not limited by the accompanying drawings, and includes (e.g., all) alterations, equivalents, and alternatives that are included in the spirit and the technical scope of the present disclosure.

The terms including ordinal numbers such as “first,” “second,” and the like may be used to describe various constituent elements, but the constituent elements are not limited by the terms. These terms are used to distinguish one constituent element from another constituent element.

When one constituent element is described as being “coupled” or “connected” to another constituent element, it should be understood that one constituent element can be coupled or connected directly to another constituent element, and an intervening constituent element can also be present between the constituent elements. When one constituent element is described as being “coupled directly to” or “connected directly to” another constituent element, it should be understood that no intervening constituent element is present between the constituent elements.

Singular expressions include plural expressions unless clearly described as different meanings in the context.

In the present specification, it should be understood the terms “comprises,” “comprising,” “includes,” “including,” “containing,” “has,” “having” or other variations thereof are inclusive and therefore specify the presence of stated features, integers, steps, operations, elements, components, or combinations thereof, but do not preclude the presence or addition of one or more other features, integers, steps, operations, elements, components, or combinations thereof.

Hereinafter, a cooling apparatus for a power module according to the exemplary embodiment of the present disclosure will be described with reference to the accompanying drawings.

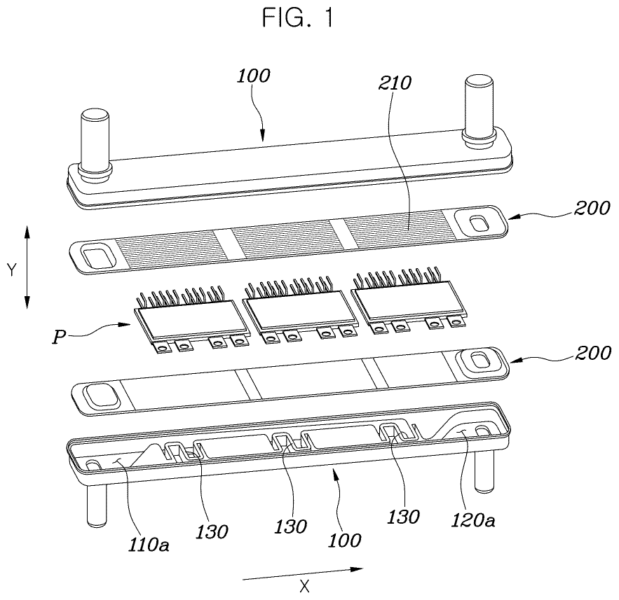

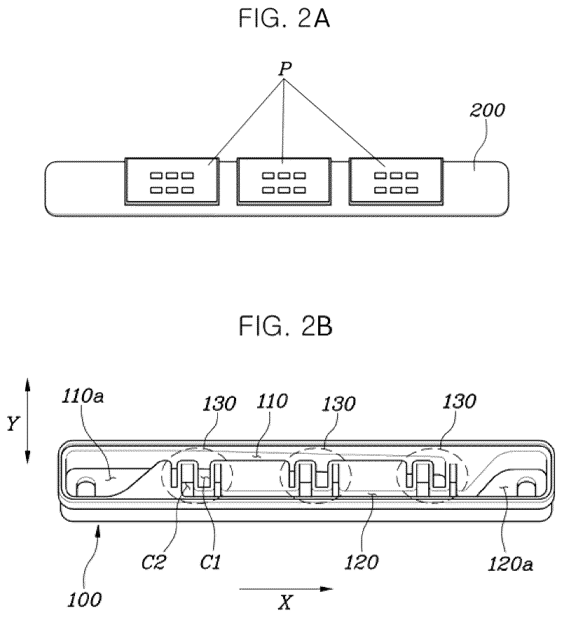

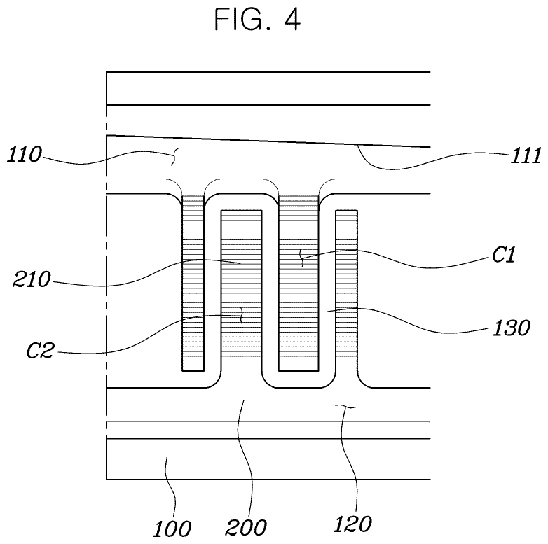

As illustrated in FIGS. 1 to 4, the cooling apparatus for a power module according to the present disclosure includes a plurality of power modules P disposed to be spaced apart from one another, a manifold cover 100 in which an inlet path 110 and an outlet path 120 extend in a first direction so that a cooling fluid flows therethrough, the inlet path 110 and the outlet path 120 are disposed to be spaced apart from each other in a second direction Y intersecting the first direction X, a plurality of cooling channel parts 130 are disposed in parallel in the first direction between the inlet path 110 and the outlet path 120 and matched with the power modules P, and the cooling channel parts 130 each include a first channel C1 configured to communicate with the inlet path 110, and a second channel C2 configured to communicate with the outlet path 120, and a fin plate 200 embedded in the manifold cover 100, configured to adjoin the power modules P, and having a plurality of cooling fins 210 extending in the first direction X so that the cooling fluid introduced into the first channel C1 flows between the cooling fins 210 and then flows to the second channel C2.

In the description of the present disclosure, the first direction X may be a direction in which the cooling fluid flows in the manifold cover 100. That is, the manifold cover 100 extends in a longitudinal direction, and an inlet and an outlet are disposed at two opposite ends of the manifold cover 100, such that the first direction X may be a direction from the left side to the right side based on the drawings. The second direction Y may be a direction orthogonal to the first direction X and may be an upward/downward direction based on the drawings.

The manifold cover 100 is formed such that the cooling fluid flows therein. The manifold cover 100 has the inlet path 110 through which the cooling fluid is introduced and flows, and the outlet path 120 through which the cooling fluid, which has exchanged heat with the power modules P, is discharged.

The inlet path 110 and the outlet path 120 extend in the first direction X and are disposed to be spaced apart from each other in the second direction Y. In addition, the cooling channel parts 130 are provided between the inlet path 110 and the outlet path 120, such that the cooling fluid may pass over the cooling fins 210 of the fin plate 200 by the cooling channel parts 130 and flow from the inlet path 110 to the outlet path 120.

The cooling channel part 130 has the first channel C1 and the second channel C2. A side of the first channel C1 adjacent to the inlet path 110 is opened, and a side of the first channel C1 adjacent to the outlet path 120 is closed, such that the cooling fluid introduced into the first channel C1 may flow to the cooling fins 210 of the fin plate 200. A side of the second channel C2 adjacent to the inlet path 110 is closed, and a side of the second channel C2 adjacent to the outlet path 120 is opened, such that the cooling fluid introduced from the cooling fins 210 may flow to the outlet path 120.

The fin plate 200 is embedded in the manifold cover 100 and has the cooling fins 210 facing the cooling channel parts 130. In this case, the cooling fin 210 extends in the first direction X and is formed to traverse the first channel C1 and the second channel C2, such that the cooling fluid is introduced from the inlet path 110 into the first channel C1 and then flows between the cooling fins 210, and the cooling fluid having passed over the cooling fins 210 flows to the outlet path 120 through the second channel C2.

As described above, the cooling fluid flowing in the manifold cover 100 flows from the inlet path 110, passes through the cooling channel parts 130, and flows to the outlet path 120. That is, during a process in which the cooling fluid flows from the inlet path 110, passes through the cooling channel parts 130, and flows to the outlet path 120, an impingement jet cooling structure is implemented as the cooling fluid passes over the cooling fins 210 of the fin plate 200. In this case, the impingement jet cooling refers to a way of eliminating heat by spraying cooling air directly to a high-temperature wall surface to obtain a locally high heat transfer effect. In order to actively implement the impingement jet cooling effect, a turbulent flow is utilized instead of a laminar flow. In this case, the turbulent flow refers to a flow having velocity components in a direction perpendicular to a flow direction, e.g., a flow with irregularity, diffusibility, and 3D vorticity in the upward, downward, leftward, and rightward directions instead of the flow direction. When the turbulent flow is created around an object, a cooling area and mixing of the cooling fluid may be increased, and the cooling efficiency may be improved.

In the present disclosure, the performance in cooling the power modules P may be provided (e.g., ensured) by generating the impingement jet cooling effect by the flow of the cooling fluid (e.g., sequentially) flowing to the first channel C1, the cooling fin 210, and the second channel C2 in the cooling channel parts 130.

Meanwhile, the plurality of cooling channel parts 130 are spaced apart from one another in the first direction X in accordance with intervals, at which the plurality of power modules P are disposed, and the plurality of cooling channel parts 130 are connected in parallel to the inlet path 110 and the outlet path 120, such that the cooling fluid flowing through the first inlet path 110 is (e.g., simultaneously) distributed and flows to the cooling channel parts 130, thereby reducing a loss of flow pressure of the cooling fluid and (e.g., substantially) preventing cooling imbalance of the power modules P with (e.g., by means of) the cooling channel parts 130. That is, the plurality of cooling channel parts 130 are connected to the inlet path 110 and the outlet path 120 by the parallel structure, and the cooling fluid (e.g., simultaneously) flows to the cooling channel parts 130, such that an increase in loss of flow pressure caused by stagnation of the flow of the cooling fluid is (e.g., substantially) prevented, the fluidity of the cooling fluid is improved, and the impingement jet cooling effect is provided (e.g., ensured) as the cooling fluid passes over the cooling fins 210 in the cooling channel part 130. Further, because the cooling fluid is (e.g., simultaneously) distributed and flows in the cooling channel parts 130, which may prevent or minimize a deterioration in performance of the power module P caused when any one power module P is overcooled or cannot be cooled.

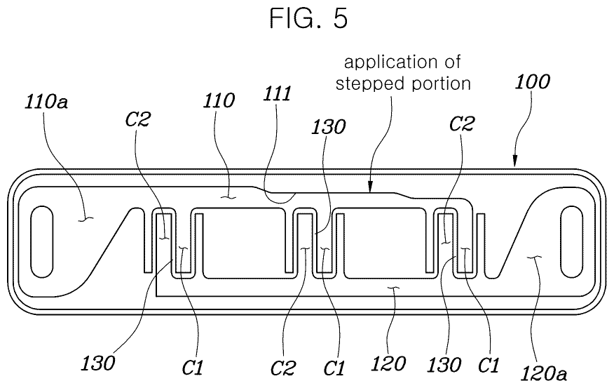

Various embodiments according to the present disclosure are illustrated in FIGS. 5 to 8.

In the description of the present disclosure, three power modules P are provided, such that three cooling channel parts 130 are provided, and the cooling fins 210 are formed in three regions in accordance with the power modules P. This configuration may be changed depending on the specifications of the power module P, and the present disclosure is not limited thereto.

The manifold cover 100 may be formed such that a cross-sectional area of the inlet path 110 decreases in the first direction X.

Because the manifold cover 100 is formed such that the cross-sectional area of the inlet path 110 gradually decreases in the first direction X, e.g., the flow direction of the cooling fluid as described above, the flow of the cooling fluid is guided in a direction away from the portion where the cooling fluid is introduced. This configuration is made by an axial flow (Vena Contracta). Because the cross-sectional area of the inlet path 110 gradually decreases in the first direction X, the flow of the cooling fluid is contracted, such that the cooling fluid may (e.g., smoothly) flow even in the cooling channel part 130 distant from the portion where the cooling fluid is introduced.

Therefore, the cooling fluid flowing in the inlet path 110 (e.g., sequentially) flows to the plurality of cooling channel parts 130, and the cooling fluid is distributed to the cooling channel parts 130 without being biased to any one cooling channel part 130, such that a flow velocity of the cooling fluid may be stabilized, and the power modules P may be cooled in a balanced manner.

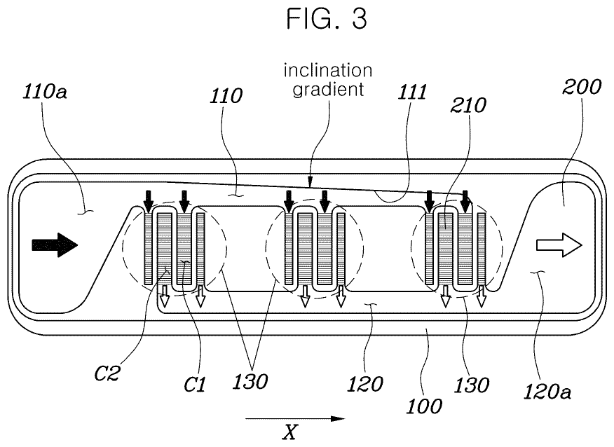

In one embodiment, as illustrated in FIG. 3, the manifold cover 100 may be formed such that an inner wall surface 111 opposite to the cooling channel part 130 is gradient toward the cooling channel part 130 in the first direction X.

That is, the manifold cover 100 may be formed such that the inner wall surface 111 gradually increases in thickness in the first direction X and is gradient. Therefore, the cross-sectional area of the inlet path 110 gradually decreases in the first direction X, such that the flow of the cooling fluid is guided in the direction away from the portion where the cooling fluid is introduced. Therefore, the cooling fluid flowing in the inlet path 110 may be distributed to the cooling channel parts 130 in a (e.g., substantially) balanced manner, the flow velocity of the cooling fluid may be stabilized, and the power modules P may be cooled in a (e.g., substantially) balanced manner.

As another embodiment, as illustrated in FIG. 5, the manifold cover 100 may be formed such that the inner wall surface 111 opposite to the cooling channel part 130 is gradually stepped and protrudes toward the cooling channel part 130 in the first direction X.

A position, at which the inner wall surface 111 of the manifold cover 100 protrudes inward and is stepped, may be a portion facing the cooling channel part 130, and the inner wall surface 111 may be stepped from the portion facing the second cooling channel part 130 based on the direction in which the cooling fluid is introduced. The inner wall surface 111 of the manifold cover 100 may increase in protruding length in the first direction X and have a shape protruding in a stepped shape.

Therefore, in the inlet path 110, the inner wall surface 111 facing the cooling channel parts 130 protrudes inward and increases in protruding length in the first direction X, such that a cross-sectional area of the inlet path 110 decreases in the first direction X. Therefore, in the inlet path 110, the flow of the cooling fluid is guided in the direction away from the portion where the cooling fluid is introduced, such that the flow velocity of the cooling fluid may be stabilized, the cooling fluid may be distributed to the cooling channel parts 130 in a balanced manner, and the power modules P may be cooled in a balanced manner.

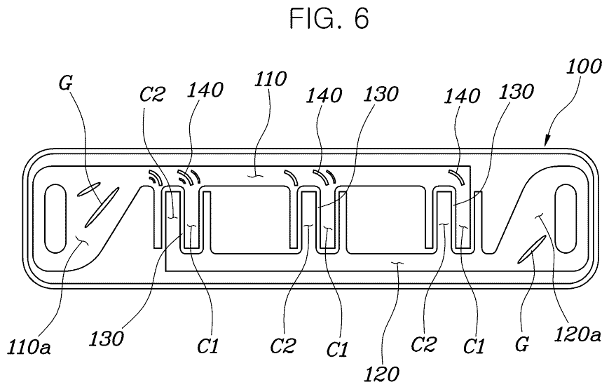

Meanwhile, in still another embodiment, as illustrated in FIG. 6, a plurality of flow rate distribution portions 140 are formed in the inlet path 110 of the manifold cover 100 in the first direction X and matched with the cooling channel parts 130. The flow rate distribution portion 140 may be formed such that a part of the cooling fluid flowing in the inlet path 110 moves to each of the cooling channel parts 130.

The flow rate distribution portion 140 may be formed on the manifold cover 100 or formed by the fin plate 200.

The flow rate distribution portions 140 are disposed in the inlet path 110 and matched with the cooling channel parts 130, thereby guiding the flow so that a part of the cooling fluid flowing in the inlet path 110 flows to the cooling channel parts 130.

The flow rate distribution portions 140 matched with the cooling channel parts 130 may be formed such that the flow rate of the cooling fluid is (e.g., sequentially and gradually) increased in the first direction X.

Therefore, the flow rate distribution portions 140 may be configured be different in shapes or numbers so that the flow rate of the cooling fluid guided to the cooling channel parts 130 gradually increases in the first direction X.

For example, the flow rate distribution portion 140 may extend obliquely or curvedly in the first direction X.

As can be seen in FIG. 6, the flow rate distribution portions 140 are disposed in the inlet path 110 and formed in panel shapes extending obliquely or curvedly, such that the flow directions of the cooling fluid flowing in the inlet path 110 may be changed by the shapes of the flow rate distribution portions 140, and the cooling fluid may be distributed to the cooling channel parts 130.

The shapes or number of flow rate distribution portions 140 may be determined depending on the flow rate of the cooling fluid that flows to the cooling channel parts 130. The determination criteria may be set so that the flow rate of the cooling fluid flowing to the cooling channel parts 130 increases in the direction away from the portion where the cooling fluid is introduced.

Because the flow rate distribution portions 140 are configured such that the flow rate of the cooling fluid guided to the cooling channel parts 130 gradually increases in the first direction X as described above, the flow rate of the cooling fluid flowing to the cooling channel parts 130 may be adjusted, and the cooling fluid may be distributed to the cooling channel parts 130 in a balanced manner.

Meanwhile, the manifold cover 100 has an inlet portion 110a formed at one side of the inlet path 110 so that the cooling fluid is introduced through the inlet portion 110a, and an outlet portion 120b formed at the other side of the outlet path 120 so that the cooling fluid is discharged through the outlet portion 120b.

The inlet portion 110a may have an inlet through which the cooling fluid is introduced, the outlet portion 120b may have an outlet through which the cooling fluid is discharged, and the inlet and the outlet may be respectively disposed at two opposite ends of the manifold cover 100. Therefore, the cooling fluid introduced through the inlet may flow from the inlet path 110 to the outlet path 120 through the cooling channel parts 130 and be discharged through the outlet from the outlet path 120.

Meanwhile, guide portions G may be respectively formed in the inlet portion 110a and the outlet portion 120b and guide the flow of the cooling fluid.

The guide portion G at the side of the inlet portion 110a extends so that the cooling fluid introduced through the inlet flows toward the inlet path 110, and the guide portion G at the side of the outlet portion 120b extends so that the cooling fluid flowing through the outlet path 120 flows toward the outlet.

As described above, the guide portions G may be respectively provided in the inlet portion 110a and the outlet portion 120b. The guide portion G provided in the inlet portion 110a extends from the inlet toward the inlet path 110 so that the cooling fluid introduced through the inlet flows to the inlet path 110. The guide portion G provided in the outlet portion 120b is formed such that the cooling fluid flowing through the outlet path 120 flows toward the outlet.

Therefore, the flow of the cooling fluid flowing through the inlet portion 110a, the inlet path 110, the outlet path 120, and the outlet portion 120b in the manifold cover 100 is stabilized, a loss of flow pressure is reduced, and the stabilization of the flow provides (e.g., ensures) the fluidity of the cooling fluid in the cooling channel part 130, thereby improving the cooling performance.

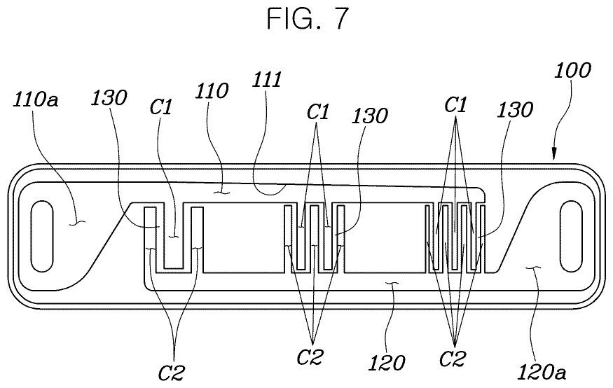

Meanwhile, as illustrated in FIG. 7, the plurality of cooling channel parts 130 are configured such that the number of first channels C1 or the number of second channels C2 gradually increases in the first direction X.

As described above, each of the cooling channel parts 130 of the manifold cover 100 is configured such that the number of first channels C1 or the number of second channels C2 increases in the first direction X, e.g., the flow direction of the cooling fluid. Therefore, the number of first channels C1 or the number of second channels C2 is relatively small in the cooling channel part 130 into which the cooling fluid is introduced first in comparison with the cooling channel part 130 at the downstream side, such that the flow rate of the cooling fluid decreases. In addition, the number of first channels C1 or the number of second channels C2 is large in the cooling channel part 130 at the downstream side in comparison with the cooling channel part 130 at the upstream side, such that the flow rate of the cooling fluid increases.

As described above, a difference in flow rates between the cooling fluids flowing in the cooling channel parts 130 occurs in the flow of the cooling fluid flowing in the first direction X, such that the cooling fluid may be distributed to the cooling channel parts 130 in a balanced manner, and a temperature distribution in the power modules P may be balanced.

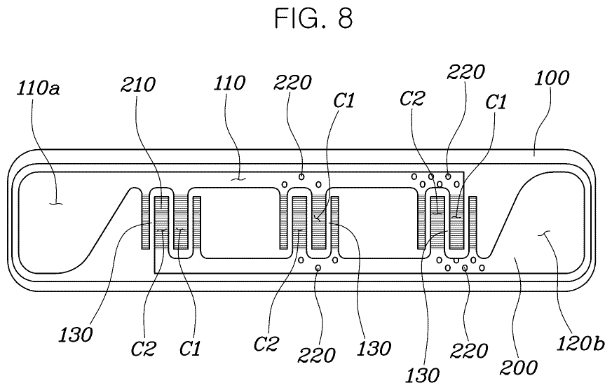

Meanwhile, as illustrated in FIG. 8, the fin plate 200 may have a plurality of fluid diffusion portions 220 formed on a part of the inlet path 110 or the outlet path 120 or around the cooling channel parts 130.

The fluid diffusion portions 220 may be provided on any one of or both the inlet path 110 and the outlet path 120 and may be disposed to be matched with the cooling channel parts 130, thereby improving the fluidity of the cooling fluid before the cooling fluid is introduced into the cooling channel part 130 or after the cooling fluid passes through the cooling channel parts 130.

The fluid diffusion portion 220 may include one or more protrusions protruding from the fin plate 200. The number of protrusions of each of the fluid diffusion portions 220 may gradually increase in the first direction.

Therefore, a difference in flow resistance of the cooling fluid occurs in the first direction X from the inlet path 110 or the outlet path 120, such that the flow rate of the cooling fluid flowing in the cooling channel parts 130 may be appropriately distributed.

That is, the fluidity of the cooling fluid may be adjusted as the number of fluid diffusion portions 220 matched with the cooling channel parts 130 increases in the first direction X from the inlet path 110.

Specifically, because the number of fins of the fluid diffusion portions 220 formed around the cooling channel part 130 at the upstream side is relatively small, the cooling fluid flowing in the first direction X from the inlet path 110 is less affected by the fluid diffusion portions 220. Therefore, the flow rate of the cooling fluid flowing through the cooling channel part 130 at the upstream decreases, such that the flow rate of the cooling fluid flowing to the downstream side may be provided (e.g., ensured).

Meanwhile, because the number of fins of the fluid diffusion portions 220 formed around the cooling channel part 130 at the downstream side is larger than that at the upstream side, a degree to which the flow is affected by the fluid diffusion portions 220 increases. Therefore, the flow rate of the cooling fluid diffused by the fluid diffusion portions 220 increases toward the downstream side, such that the flow rate of the cooling fluid flowing to the cooling channel part 130 may increase.

In addition, because the number of fins of the fluid diffusion portions 220 matched with the cooling channel parts 130 increases in the first direction X from the outlet path 120, the cooling fluid flowing in the outlet path 120 may be diffused toward the outlet in the first direction X, such that the flow of the cooling fluid may be stabilized, and the cooling fluid may flow at a (e.g., substantially) constant flow velocity.

The plurality of protrusions of the fluid diffusion portions 220 may be spaced apart from one another in the first direction X and intersect in the second direction Y, and cross-sections thereof may be formed in polygonal or circular shapes.

As described above, the fluid diffusion portions 220 matched with the cooling channel parts 130 may affect the flow of the cooling fluid and be involved in the flow of the fluid. The flow of the cooling fluid flowing through the inlet path 110 or the outlet path 120 may be optimized by changing the number or shapes of the protrusions constituting the fluid diffusion portions 220 in accordance with the cooling channel parts 130.

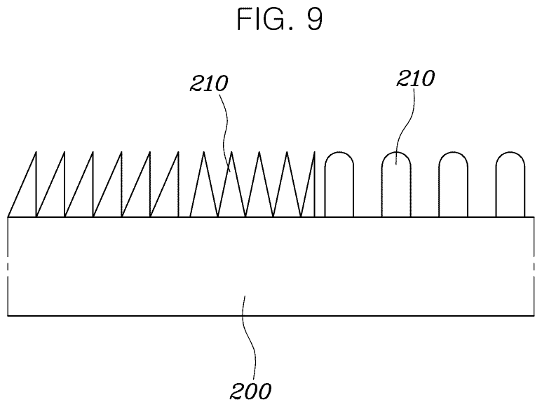

Meanwhile, as illustrated in FIG. 9, the cooling fins 210 protrude from the fin plate 200. A cross-sectional area of a protruding end may gradually decrease in a protruding direction.

A cross-sectional shape of the end of the cooling fin 210 may be a triangular or curved shape. That is, the shape of the cross-section may be any one of a right triangular shape, an isosceles triangular shape, or a semi-circular shape. However, the present disclosure is not limited thereto.

In addition, the cooling fins 210 may be spaced apart from one another at predetermined intervals and formed alternately. The cooling fins 210 may be repeatedly formed without an interval.

With various embodiments according to the present disclosure, the cooling fluid flowing through the inlet path 110 and the outlet path 120 in the manifold cover 100 is (e.g., constantly) distributed to the cooling channel parts 130, a (e.g., constant) flow velocity of the cooling fluid is provided (e.g., ensured), and the flow of the cooling fluid is (e.g., substantially) stabilized.

In addition, the cooling channel parts 130 matched with the power modules P may be connected to the inlet path 110 and the outlet path 120 by the parallel connection structure, such that the cooling fluid may be distributed in a (e.g., substantially) balanced manner, a loss of fluid flow pressure may be reduced, and the power modules P may be (e.g., uniformly) cooled.

In addition, in the cooling channel part 130, the vertical turbulent flow components of the cooling fluid are created by the first channel C1, the cooling fin 210, and the second channel C2, and the impingement jet cooling structure is implemented, such that the performance in cooling the power modules P is improved.

While the specific embodiments of the present disclosure have been illustrated and described, the present disclosure may be variously modified and changed without departing from the technical spirit of the present disclosure defined in the appended claims.

What is claimed is:

1. A cooling apparatus for a power module, the cooling apparatus comprising:
a plurality of power modules disposed to be spaced apart from one another;
a manifold cover in which an inlet path and an outlet path extend in a first direction so that a cooling fluid flows therethrough, the inlet path and the outlet path are disposed to be spaced apart from each other in a second direction intersecting the first direction, a plurality of cooling channel parts are disposed in parallel in the first direction between the inlet path and the outlet path and matched with the power modules, and the cooling channel parts each include a first channel configured to communicate with the inlet path, and a second channel configured to communicate with the outlet path; and
a fin plate embedded in the manifold cover, configured to adjoin the power modules, and having a plurality of cooling fins extending in the first direction so that the cooling fluid introduced into the first channel flows between the cooling fins and then flows to the second channel.

2. The cooling apparatus of claim 1, wherein the manifold cover is formed such that a cross-sectional area of the inlet path decreases in the first direction.

3. The cooling apparatus of claim 1, wherein the manifold cover is formed such that an inner wall surface opposite to the cooling channel parts is gradient toward the cooling channel parts in the first direction.

4. The cooling apparatus of claim 1, wherein the manifold cover is formed such that an inner wall surface opposite to the cooling channel parts is gradually stepped and protrudes toward the cooling channel parts in the first direction.

5. The cooling apparatus of claim 1, wherein a plurality of flow rate distribution portions are formed in the inlet path of the manifold cover in the first direction and matched with the cooling channel parts, and at least one of the flow rate distribution portions is formed such that a part of the cooling fluid flowing in the inlet path moves to each of the cooling channel parts.

6. The cooling apparatus of claim 5, wherein at least one of the flow rate distribution portions extends obliquely or curvedly in the first direction.

7. The cooling apparatus of claim 5, wherein at least one of the flow rate distribution portions matched with each of the cooling channel parts is formed such that a flow rate of the cooling fluid sequentially and gradually increases in the first direction.

8. The cooling apparatus of claim 1, wherein the manifold cover has an inlet portion formed at one side of the inlet path so that the cooling fluid is introduced through the inlet portion, and an outlet portion formed at the other side of the outlet path so that the cooling fluid is discharged through the outlet portion, and guide portions are respectively formed in the inlet portion and the outlet portion and guide the flow of the cooling fluid.

9. The cooling apparatus of claim 8, wherein at least one of the guide portions at a side of the inlet portion extends so that the cooling fluid introduced through an inlet flows toward the inlet path, and
wherein at least one of the guide portions at a side of the outlet portion extends so that the cooling fluid flowing in the outlet path flows toward an outlet.

10. The cooling apparatus of claim 1, wherein the plurality of cooling channel parts are configured such that a number of first channels or a number of second channels gradually increases in the first direction.

11. The cooling apparatus of claim 1, wherein the fin plate has a plurality of fluid diffusion portions formed in a part of the inlet path or the outlet path or formed around the cooling channel parts.

12. The cooling apparatus of claim 11, wherein at least one of the plurality of fluid diffusion portions includes one or more protrusions protruding from the fin plate, and a number of protrusions of at least one of the fluid diffusion portion gradually increases in the first direction.

13. The cooling apparatus of claim 12, wherein the one or more protrusions of the at least one of the fluid diffusion portion are spaced apart from one another in the first direction and intersect in the second direction.

14. The cooling apparatus of claim 11, wherein a cross-section of at least one of the fluid diffusion portions is formed in a polygonal or circular shape.

15. The cooling apparatus of claim 1, wherein at least one of the cooling fins protrudes from the fin plate, and a cross-sectional area of a protruding end gradually decreases in a protruding direction.

16. The cooling apparatus of claim 1, wherein a cross-sectional shape of an end of at least one of the cooling fins is a triangular or curved shape.
